(19) United States
(12) Patent Application Publication
(10) Pub. No.: US 2015/0155141 A1
(43) Pub. Date: Jun. 4, 2015

(54) PLASMA PROCESSING APPARATUS

(71) Applicant: TOKYO ELECTRON LIMITED, Tokyo (JP)

(72) Inventors: Yasuo KOBAYASHI, Miyagi (JP); Masahide IWASAKI, Miyagi (JP); Koji YAMAGISHI, Miyagi (JP)

(73) Assignee: TOKYO ELECTRON LIMITED, Tokyo (JP)

(21) Appl. No.: 14/557,569

(22) Filed: Dec. 2, 2014

(30) Foreign Application Priority Data
Dec. 3, 2013 (JP) 2013-250162

(51) Int. Cl. H01J 37/32

(52) U.S. Cl. CPC H01J 37/32513; H01J 37/32192; H01J 37/32522

(57) ABSTRACT

A plasma processing apparatus of the present disclosure includes a processing container provided with an opening to carry an object to be processed (“workpiece”) into or out of a chamber adjacent to the processing container; a microwave introducing mechanism configured to introduce microwaves into the processing container; an exhaust device configured to evacuate the processing container; and a thermal insulating member provided between an outer surface of a gate valve that is provided near the opening and the chamber adjacent to the processing container. The thermal insulating member is coated with a conductive film at least on a surface of the thermal insulating member facing the outer surface of the gate valve, a surface of the thermal insulating member facing the chamber adjacent to the processing container, and a surface of the thermal insulating member exposed to outer air.

### CROSS-REFERENCE TO RELATED APPLICATIONS

This application is based on and claims priority from Japanese Patent Application No. 2013-250162, filed on Dec. 3, 2013 with the Japan Patent Office, the disclosure of which is incorporated herein in its entirety by reference.

### TECHNICAL FIELD

The present disclosure relates to a plasma processing apparatus in which plasma is generated using a processing gas to process an object to be processed (“workpiece”).

### BACKGROUND

Conventionally, a plasma processing apparatus has been known in which a predetermined plasma processing is performed on a workpiece such as, for example, a semiconductor wafer and plasma is generated by introducing microwaves into a processing container. In such a plasma processing apparatus using microwaves, high density plasma having a low electron temperature may be generated under a low pressure in the processing container, and, for example, a film forming processing or an etching processing is performed by the generated plasma.

As the plasma processing apparatus, for example, a plasma processing apparatus disclosed in Japanese Patent Laid-Open Publication No. 2008-13816 has been proposed. In such a plasma processing apparatus, a processing gas and microwaves are supplied into a processing apparatus and the processing gas is converted into plasma by the microwaves. Then, a plasma processing is performed on a wafer that is carried in and placed in the apparatus using the processing gas converted into plasma.

Here, in a general plasma processing apparatus, which is represented by Japanese Patent Laid-Open Publication No. 2008-13816, a transfer chamber is positioned adjacent to the plasma processing apparatus so as to perform transfer or carry-in/out of wafers to/from the processing apparatus. Since the plasma processing apparatus is required to be sealed in a vacuum state during a processing, an openable/closable gate valve for carry-in/out of wafers is provided between the plasma processing apparatus and the transfer chamber. In the plasma processing apparatus and the transfer chamber which are configured as described above, it is necessary to prevent leakage of microwaves from the processing apparatus to the outside from the viewpoint of safety. Hence, various methods have been suggested in the related art.

For example, Japanese Patent Laid-Open Publication No. 2008-13816 discloses a plasma processing apparatus in which a hermetic sealing member (an O-ring) is provided to hermetically seal the valve body of the gate valve, and a groove-type microwave reflecting mechanism is provided in an outer peripheral portion of the hermetic sealing member.

Further, a transfer mechanism (e.g., a transfer robot) is provided in the conveyance chamber for a general plasma processing apparatus to transfer wafers, and the inside of the transfer chamber is maintained at a temperature of about 50° C. from the viewpoint of suppressing malfunction of the transfer mechanism. Meanwhile, it is known that the temperature in the plasma processing apparatus reaches, for example, about 180° C., which is a general plasma processing temperature, during the processing. Therefore, since there is a large temperature difference between the plasma processing apparatus and the transfer chamber in some cases, a thermal insulation material made of an insulator is provided between both sides.

### SUMMARY

The present disclosure provides a plasma processing apparatus including a processing container provided with an opening to carry an object to be processed (“workpiece”) into or out of a chamber adjacent to the processing container; a microwave introducing mechanism configured to introduce microwaves into the processing container; an exhaust device configured to evacuate the processing container; and a thermal insulating member provided between an outer surface of a gate valve that is provided near the opening and the chamber adjacent to the processing container. The thermal insulating member is coated with a conductive film at least on a surface facing the outer surface of the gate valve, a surface facing the chamber adjacent to the processing container, and a surface exposed to outer air.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating a plasma processing apparatus according to an exemplary embodiment of the present disclosure.

FIG. 2 is a cross-sectional view illustrating a portion in the vicinity of a carry-in/out port provided through a side wall of a processing container according to an exemplary embodiment of the present disclosure in an enlarged scale.

FIG. 3 is a view illustrating a portion in the vicinity of a sealing member.

FIGS. 4A and 4B are explanatory views schematically illustrating a verification device for leakage of microwaves in a thermal insulating member. FIG. 4A illustrates a case where no conductive film is provided, and FIG. 4B illustrates a case where a conductive film is provided.

FIG. 5 is a cross-sectional view illustrating a portion in the vicinity of a carry-in/out port provided through a side wall of a processing container according to another exemplary embodiment of the present disclosure in an enlarged scale.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

In the plasma processing apparatus as described in Japanese Patent Laid-Open Publication No. 2008-13816, the hermetic sealing member on the valve body of the gate valve or the microwave reflecting mechanism is provided so as to suppress the leakage of microwaves. However, since a gap is present between the valve body and the outer surface of the plasma processing apparatus, the leakage of microwaves may not be suppressed sufficiently. Further, Japanese Patent Laid-Open Publication No. 2008-13816 fails to mention about the leakage of microwaves in the thermal insulating material between the plasma processing apparatus and the transfer chamber. Therefore, there is a room for further improvement as a technique for suppressing the leakage of microwaves.

The present disclosure has been made in consideration of the above-mentioned problems, and an object of the present disclosure is to efficiently suppress the leakage of microwaves from the inside of the processing apparatus with a simple structure, without impairing the thermal insulation between the plasma processing apparatus and the transfer chamber.

According to an aspect of the present disclosure, a plasma processing apparatus includes a processing container provided with an opening to carry an object to be processed (“workpiece”) into or out of a chamber adjacent to the processing container; a microwave introducing mechanism configured to introduce microwaves into the processing container; an exhaust device configured to evacuate the processing container; and a thermal insulating member provided between an outer surface of a gate valve that is provided near the opening and the chamber adjacent to the processing container. The thermal insulating member is coated with a conductive film at least on a surface facing the outer surface of the gate valve, a surface facing the chamber adjacent to the processing container, and a surface exposed to outer air.

According to the present disclosure, since the thermal insulating member, which is provided between the processing container and the chamber adjacent to the processing container, is coated with the conductive film, it is possible to prevent or suppress the microwaves from being leaked from the inside of the processing container to the outside through the thermal insulating member as in the prior art, while securing the thermal insulation. Therefore, the safety of the plasma processing apparatus is improved so that the plasma processing such as, for example, a film forming processing or an etching processing may be performed stably and properly.

The conductive film may be coated on a whole outer peripheral surface of the thermal insulating member.

The conductive film may be coated by a plating method or a thermal spraying method.

A thickness of the conductive film may be 5 μm to 100 μm.

The thermal insulating member may be formed of an insulating resin.

According to the present disclosure, the leakage of microwaves from the inside of the processing apparatus may be suppressed efficiently with a simple structure, without impairing the thermal insulation between the plasma processing apparatus and the transfer chamber.

Hereinafter, exemplary embodiments of the present disclosure will be described with reference to the drawings. In the present specification and drawings, the same reference numerals are given to components having substantially the same functional configuration and the redundant descriptions thereof will be omitted. In the plasma processing apparatus 1 of the present exemplary embodiment, a plasma chemical vapor deposition (CVD) processing is performed on a surface of a wafer W serving as a workpiece to form a SiN film (silicon nitride film) on the surface of the wafer W.

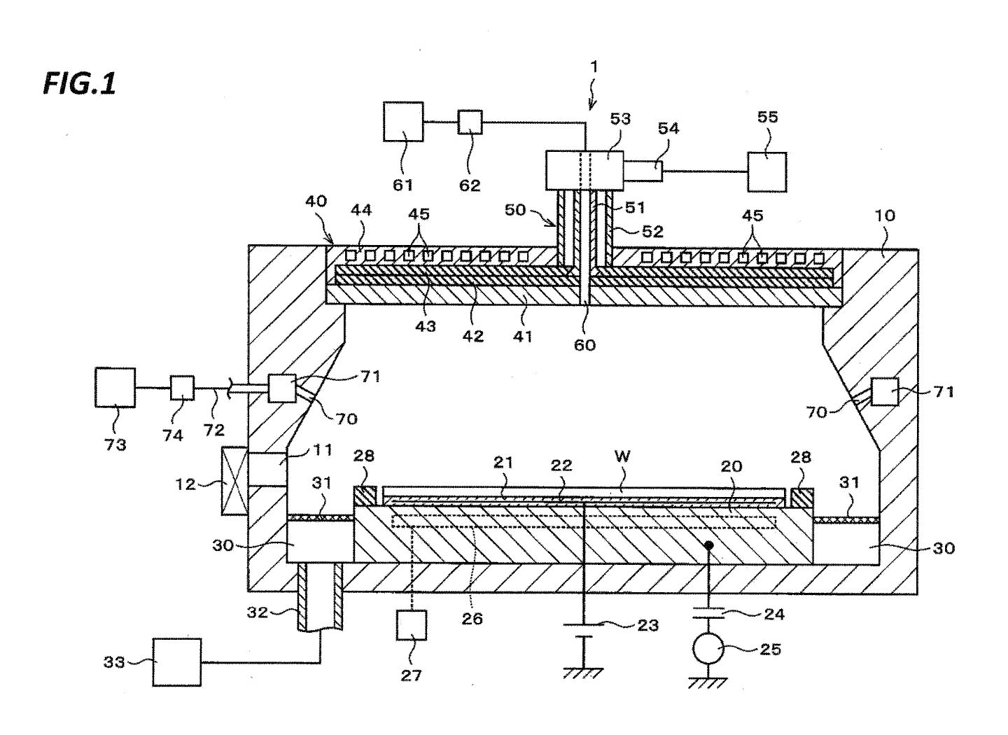

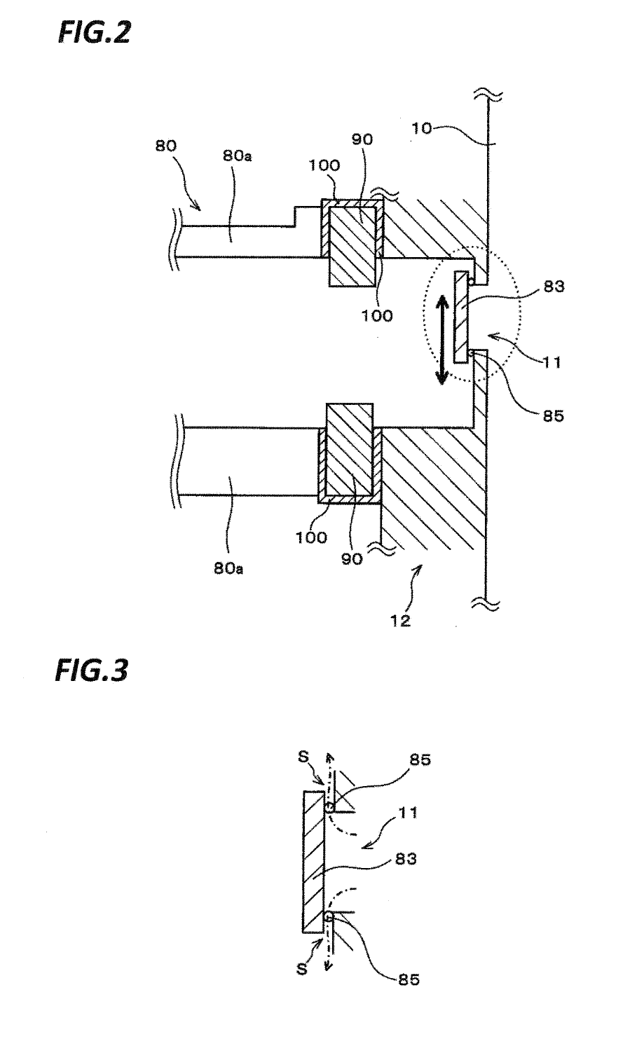

The plasma processing apparatus 1 is provided with a processing apparatus 10 as illustrated in FIG. 1. The processing container 10 has a substantially cylindrical shape with an opened ceiling, and a radial line slot antenna 40 to be described later is disposed in the ceiling opening. Further, a carry-in/out port 11 of a wafer W is formed in a side wall of the processing container 10, and a gate valve 12 is provided in the carry-in/out port 11. In addition, the processing container 10 is configured such that the inside thereof is sealable. The configurations of the carry-in/out port 11 and the gate valve 12 are illustrated schematically in FIG. 1, and the detailed configurations thereof will be described later with reference to FIG. 2. Further, the processing container 10 is made of metal such as aluminum or stainless steel. The processing container 10 is grounded.

A placing table 20 is provided on a bottom surface of the processing container 10 as a placing unit to place a wafer W thereon. The placing table 20 has a cylindrical shape. Further, the placing table 20 is made of, for example, aluminum.

An electrostatic chuck 21 is provided on a top surface of the placing table 20. The electrostatic chuck 21 has a configuration in which an electrode 22 is interposed between insulating materials. The electrode 22 is connected to a direct current (DC) power supply 23 provided outside the processing container 10. The wafer W may be electrostatically attracted on the placing table by a Coulomb force generated on the surface of the placing table 20 by the DC power supply 23.

Further, the placing table 20 may be connected with a high-frequency power supply 25 for RF bias via a condenser 24. The high-frequency power supply 25 outputs a predetermined power having a certain frequency suitable to control energy of ions drawn to the wafer W, for example, a high-frequency of 13.56 MHz.

Further, a temperature adjusting mechanism 26 is provided inside the placing table 20 in which, for example, a cooling medium flows through the temperature adjusting mechanism 26. The temperature adjusting mechanism 26 is connected to a liquid temperature adjusting unit 27 configured to control a temperature of the cooling medium. The temperature of the cooling medium may be controlled by the liquid temperature adjusting unit 27 to control the temperature of the placing table 20. As a result, the wafer W placed on the placing table 20 may be maintained at a predetermined temperature. Further, the placing table 20 is formed with a gas passage (not illustrated) configured to supply a heat transfer medium such as, for example, helium (He) gas onto a rear surface of the wafer W at a predetermined pressure (back pressure).

An annular focus ring 28 is provided on the top surface of the placing table 20 to surround the wafer W on the electrostatic chuck 21. The focus ring 28 is made of an insulating material such as, for example, ceramics or quartz. The focus ring 28 functions to enhance the uniformity of the plasma processing.

Elevation pins (not illustrated) are provided below the placing table 20 to support the wafer W from the bottom and move up and down the wafer W. The elevation pins are configured to pass through through-holes (not illustrated) formed in the placing table 20 and protrude from the top surface of the placing table 20.

Around the placing table 20, an annular exhaust space 30 is formed between the placing table 20 and the side wall of the processing container 10. An annular baffle plate 31 formed with a plurality of exhaust holes is provided in the upper portion of the exhaust space 30 to uniformly exhaust an atmosphere in the processing container 10. An exhaust pipe 32 is connected to the bottom surface of the processing container 10 serving as a bottom of the exhaust space 30. The number of exhaust pipes 32 may be optionally set, and a plurality of exhaust pipes 32 may be formed circumferentially. The exhaust pipes 32 are connected to an exhaust device 33 provided with, for example, a vacuum pump. The exhaust device 33 may decompress the atmosphere in the processing container 10 to a predetermined degree of vacuum.

A radial line slot antenna 40 is provided in the ceiling opening of the processing container 10 to supply microwaves for producing plasma. The radial line slot antenna 40 is provided with a microwave transmission plate 41, a slot plate 42, a slow-wave plate 43, and a shield lid 44.

The microwave transmission plate 41 is closely fitted in the ceiling opening of the processing container 10 through a seal member (not illustrated) such as, for example, an O-ring. Accordingly, the inside of the processing container 10 is maintained hermetically. The microwave transmission plate 41 is made of, for example, quartz, Al₂O₃ or AlN. The microwave transmission plate 41 transmits microwaves.

The slot plate 42 is disposed on the top surface of the microwave transmission plate 41 and provided to be opposite to the placing table 20. The slot plate 42 is formed with a plurality of slots. The slot plate 42 functions as an antenna. The slot plate 42 is made of a conductive material such as, for example, copper, aluminum or nickel.

The slow-wave plate 43 is provided on the top surface of the slot plate 42. The slow-wave plate 43 is made of a low-loss dielectric material such as, for example, quartz, Al₂O₃ or AlN. The slow-wave plate 43 shortens the wavelength of the microwaves.

The shield lid 44 is provided on the top surface of the slow-wave plate 43 to cover the slow-wave plate 43 and the slot plate 42. A plurality of annular flow paths 45 is provided inside the shield lid 44 to circulate, for example, a cooling medium. The microwave transmission plate 41, the slot plate 42, the slow-wave plate 43, and the shield lid 44 are controlled to a predetermined temperature by the cooling medium circulating through the flow paths 45.

A coaxial waveguide 50 is connected to a central portion of the shield lid 44. The coaxial waveguide 50 is provided with an internal conductor 51 and an external tube 52. The internal conductor 51 is connected to the slot plate 42. The slot plate 42 side of the internal conductor 51 is formed conically to efficiently propagate the microwaves to the slot plate 42.

The coaxial waveguide 50 is connected with a mode converter 53 that converts the microwaves into a predetermined vibration mode, a rectangular waveguide 54, and a microwave generator 55 in this order from the coaxial waveguide 50. The microwave generator 55 generates microwaves of a predetermined frequency, for example, 2.45 GHz.

With such a configuration, the microwaves generated by the microwave generator 55 are propagated sequentially through the rectangular waveguide 54, the mode converter 53 and the coaxial waveguide 50 to be supplied into the radial line slot antenna 40, and compressed by the slow-wave plate 43 to be shortened in wavelength. After generating circularly polarized waves in the slot plate 42, the microwaves are transmitted through the microwave transmission plate 41 from the slot plate 42, and then, radiated into the processing container 10. The processing gas is converted into plasma in the processing container by the microwaves, and a plasma processing of the wafer W is performed by the plasma.

A first processing gas supply pipe 60 serving as the first processing gas supply section is provided in the central portion of the ceiling of the processing container 10, that is, the radial line slot antenna 40. The first processing gas supply pipe 60 penetrates the radial line slot antenna 40, and one end of the first processing gas supply pipe 60 is opened on the bottom surface of the microwave transmission plate 41. Further, the first processing gas supply pipe 60 penetrates the inside of the internal conductor 51 of the coaxial waveguide 50 and is inserted through the inside of the mode converter 53 so that the other end of the first processing gas supply pipe 60 is connected to a first processing gas source 61. Processing gases such as, for example, trisilylamine (TSA), N₂ gas, H₂ gas and Ar gas are stored separately in the first processing gas source 61. Among them, TSA, N₂ gas and H₂ gas are material gases for film formation, and Ar gas is a gas for plasma excitation. Hereinafter, these processing gases may be collectively referred to as a “first processing gas”. Further, a supply equipment group 62 including a valve or flow rate regulating unit for controlling the flow of the first processing gas is provided in the first processing gas supply pipe 60.

As illustrated in FIG. 1, a second processing gas supply pipe 70 serving as a second processing gas supply section is provided in the side wall of the processing container 10. A plurality of (e.g., twenty four) second processing gas supply pipes 70 is provided at equal intervals on the circumference in the side wall of the processing container 10. One end of each second processing gas supply pipe 70 is opened in the side wall of the processing container 10, and the other end is connected to a buffer section 71. Each second processing gas supply pipe 70 is disposed obliquely such that the one end is positioned below the other end.

The buffer section 71 is provided annularly inside the side wall of the processing container 10 and commonly to the plurality of second processing gas supply pipes 70. The buffer section 71 is connected with a second processing gas source 73 through the supply pipes 72. Processing gases such as, for example, trisilylamine (TSA), N₂ gas, H₂ gas and Ar gas are stored separately in the second processing gas source 73. Hereinafter, these processing gases may be collectively referred to as a “second processing gas”. Further, a supply equipment group 74 including, for example, a valve or a flow rate regulating unit for controlling the flow of the second processing gas is provided in the second processing gas supply pipes 72.

The first processing gas from the first processing gas supply pipe 60 is supplied towards the central portion of the wafer W, and the second processing gas from the second processing gas supply pipes 70 is supplied towards the outer peripheral portion of the wafer W.

Further, the processing gases, which are supplied into the processing container 10 from the first processing gas supply pipe 60 and the second processing gas supply pipes 70, respectively, may be the same as or different from each other, and each may be supplied at an independent flow rate, or at any flow ratio.

Next, descriptions will be made on the plasma processing of the wafer W performed in the plasma processing apparatus 1 having the above-mentioned configuration. In the present exemplary embodiment, a plasma film forming processing is performed on a wafer W as described above to form a SiN film on the surface of the wafer W.

First, the gate valve 12 is opened, and a wafer W is carried into the processing container 10. The wafer W is placed on the placing table 20 by the elevation pins. At this time, the DC power supply 23 is turned ON to apply a DC voltage to the electrode 22 of the electrostatic chuck 21 such that the wafer W is electrostatically attracted on the electrostatic chuck 21 by a Coulomb force of the electrostatic chuck 21. Then, after the gate valve 12 is closed and the processing container 10 is sealed, the exhaust device 33 is operated to decompress the atmosphere in the processing container 10 to a predetermined pressure, for example, 400 mTorr (53 Pa).

Then, the first processing gas is supplied from the first processing gas supply pipe 60 into the processing container 10, and the second processing gas is supplied from the second processing gas supply pipes 70 into the processing container 10. At this time, the flow rate of Ar gas supplied from the first processing gas supply pipe 60 is, for example, 100 sccm (ml/min), and the flow rate of Ar gas supplied from the second processing gas supply pipes 70 is, for example, 750 sccm (ml/min).

When the first processing gas and the second processing gas are supplied into the processing container, the microwave generator 55 is operated to generate microwaves of a predetermined power at a frequency of, for example, 2.45 GHz. The microwaves are radiated into the processing container 10 through the rectangular waveguide 54, the mode converter 53, the coaxial waveguide 50, and the radial line slot antenna 40. In the processing container 10, the processing gases are converted into plasma by the microwaves, and dissociation of the processing gases proceeds in the plasma. Consequently, a film forming processing is performed on the wafer W by the active species generated at that time. Therefore, a SiN film is formed on the surface of the wafer W.

While the plasma film forming processing is performed on the wafer W, the high-frequency power supply 25 may be turned ON to output high-frequency waves of a predetermined power at a frequency of, for example, 13.56 MHz. The high-frequency waves are applied to the placing table 20 through the condenser 24, and an RF bias is applied to the wafer W. In the plasma processing apparatus 1, since a low electron temperature of the plasma can be maintained, no damage is caused to the film. Furthermore, since molecules of the processing gases are likely to be dissociated by the high density plasma, the reaction is promoted. In addition, the application of the RF bias within an appropriate range acts to draw ions in the plasma into the wafer W. Therefore, denseness of the SiN film may be enhanced, and trap in the film may be increased.

Thereafter, when the SiN film grows and hence the SiN film having a predetermined film thickness is formed on the wafer W, the supply of the first processing gas, the second processing gas and the rectifying gas R, and the irradiation of the microwaves are stopped. Then, the wafer W is carried out from the processing container 10, and a series of the plasma film forming processings are terminated.

A configuration of a portion in the vicinity of the carry-in/out port 11 provided through a side wall of the processing container 10 according to the present exemplary embodiment is described with reference to the drawings. Further, the following descriptions will be made on a configuration in which a transfer chamber 80 serving as the chamber provided adjacent to the plasma processing apparatus 1 is connected to the processing container 10 through the carry-in/out port 11.

FIG. 2 is a cross-sectional view illustrating the portion in the vicinity of the carry-in/out port 11 provided through the side wall of a processing container 10 according to the present exemplary embodiment in an enlarged scale. As illustrated in FIG. 2, the carry-in/out port 11 is provided with a plate-shaped valve body 83 that is configured in a rectangular shape to fit the shape of the carry-in/out port 11 and has a dimension larger than that of the carry-in/out port 11. The valve body 83 is connected to a driving unit (not illustrated), and configured to switch the carry-in/out port 11 between an opened state and a closed state as the valve body 83 is moved in a vertical direction (a direction of the arrow in the figure) by the driving unit. That is, the valve body 83 is configured to be switchable between a state in which the wafer W may be transferred from the transfer chamber 80 to processing container 10 and a state in which the processing container 10 is hermitically closed. Further, the valve body 83 is provided with a frame-shaped sealing member (an O-ring) 85. The sealing member 85 is made of, for example, rubber or resin and configured to perform a hermetic sealing by being abutting onto and pressed against the outer side of the processing container 10.

Further, a thermal insulating member 90 is provided between an outer surface of the gate valve 12 and a side wall of a case 80a of the transfer chamber 80 in a shape surrounding the carry-in/out port 11. It is necessary to control the inside of the transfer chamber 80 to about 50° C., whereas the atmosphere in the processing container 10 reaches, for example, about 180° C. during the plasma processing. Therefore, the thermal insulating member 90 is provided to suppress the thermal conduction from the processing container 10. The thermal insulating member 90 may be an insulator having a high heat resistance and a low heat conductivity and is made of, for example, an insulating resin (e.g., a plastic material). As described above, since the inside of processing container 10 undergoes a high temperature, for example, about 180° C., the inside of processing container 10 is required to be made of a material having a heat resistance for the temperature.

Further, as illustrated in FIG. 2, a conductive film 100 is formed on a surface of the thermal insulating member 90 facing the outer surface of the gate valve 12 (an interface), and a surface of the thermal insulating member 90 facing the outer surface of the transfer chamber 80 (the case 80a) (an interface). Further, the same conductive film 100 is also formed on a surface of the thermal insulating member 90 exposed to the outside of the apparatus (a surface at the outer air side). The conductive film 100 is a metal film made of, for example, aluminum, and has a thickness of 5 μm to 100 μm. The conductive film 100 is coated on the surface of the thermal insulating member 90 by, for example, a plating method or a thermal spraying method.

FIG. 3 is an enlarged view of the portion in the vicinity of the sealing member 85 indicated by a circle of a broken line in FIG. 2. As illustrated in FIG. 3, even though the plasma processing is performed in the processing container 10 in a state where the valve body 83 of the gate valve 12 is closed, a small gap S is formed between the valve body 83 and the outer surface (sidewall) of the processing container 10 by the sealing member 85 provided therebetween. As described above, since the sealing member 85 is made of an insulator such as rubber or resin, microwaves are transmitted therethrough. Therefore, when the plasma processing is performed in the processing container 10, the microwaves penetrate the sealing member 85 through the gap S of the gate valve 12 and is leaked to the transfer chamber 80 side (see arrows of dashed lines in FIG. 3). Here, the microwaves leaked to the transfer chamber 80 side may further penetrate the thermal insulating member 90 made of an insulator to be leaked to the outside of the apparatus.

Accordingly, in order to suppress the microwaves leaked from the processing container 10 during the plasma processing from further penetrating the thermal insulating member 90 to be leaked to the outside of the apparatus, the present inventors have conceived a technique of coating the conductive film 100 on the outer surface of the thermal insulating member 90 as illustrated in FIG. 2. Further, the present inventors have experimentally verified which portion of the outer surface of the thermal insulating member 90 the conductive film 100 shall be coated on so as to efficiently suppress the leakage of microwaves. Hereinafter, the verification will be described with reference to the drawings and tables.

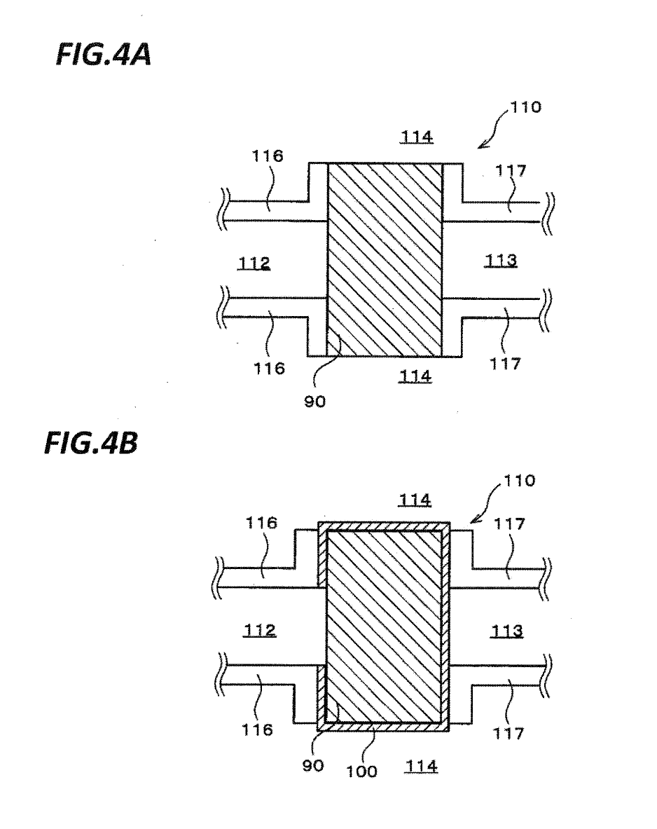

FIGS. 4A and 4B are explanatory views schematically illustrating a verification device 110 for the leakage of microwaves in the thermal insulating member 90. FIG. 4A illustrates a case where the conductive film 100 is not provided, and FIG. 4B illustrates a case where the conductive film 100 is provided. As illustrated in FIGS. 4A and 4B, the verification device 110 is configured with the thermal insulating member 90 and spaces 112, 113 formed at both sides of the thermal insulating member 90. The spaces 112, 113 are hermetically sealed. The spaces 112, 113 are assumed as the inside of the processing container 10 and the inside of the transfer chamber 80 in the present exemplary embodiment, respectively. For explanation, the left side in FIGS. 4A and 4B is assumed as the space 112 serving as the inside of the processing container 10, and the right side is assumed as the space 113 serving as the inside of the transfer chamber 80. Further, the space outside the apparatus (the space at the outer air side) is assumed as the space denoted by reference numeral “114”. Here, the case configured to surround the space 112 is denoted by the reference numeral “116”, and the case configured to surround the space 113 is denoted by the reference numeral “117”.

First, the thermal insulating member 90 non-coated with conductive film 100 was provided between the space 112 and the space 113 as illustrated in FIG. 4A, and microwaves were generated in the space 112. Then, a leakage status of the microwaves was verified.

Subsequently, the thermal insulating member 90 coated with the conductive film 100 was provided between the space 112 and the space 113 as illustrated in FIG. 4B, and microwaves were generated in the space 112. Then, a leakage status of the microwaves was verified. Further, as illustrated in FIG. 4B, the portions coated with the conductive film 100 were the interface of the case 116 and the thermal member 90, the whole lateral surface of the thermal insulating member 90 at the space 113 side, and the whole upper and lower surfaces that are in contact with the outer air among the outer surface of the thermal insulating member 90.

Table 1 as shown below represents verification results of reflection (%), transmission (%), absorption (%), and leakage (%) when input of microwaves to the thermal insulating member 90 is deemed as 100(%). In Table 1, the “non-processing” refers to a condition in which the thermal insulating member 90 was not coated with the conductive film 100 as illustrated in FIG. 4A. In addition, the “plating method” refers to a condition in which the conductive film 100 as illustrated in FIG. 4B was coated to a thickness of 5 μm by a plating method, and the “thermal spraying method” refers to a condition in which the conductive film 100 was to a thickness of 100 μm by a thermal spraying method. Further, a metal film was used as the conductive film 100.

In Table 1, the “reflection (%)” refers to a ratio in which the microwaves generated in the space 112 were input to the thermal member 90 and then reflected back to the space 112, and the “transmission (%)” refers to a ratio in which the microwaves generated in the space 112 were transmitted through the thermal member 90 and reach the space 113. In addition, the “absorption (%)” refers to a ratio in which the microwaves generated in the space 112 was absorbed to the thermal insulating member 90, and the “leakage (%)” refers to a ratio in which the microwaves were leaked to the outer space 114 at the interface between the space 112 and the thermal insulating member 90. Further, the “leakage attenuation ratio” in Table 1 refers to a microwave amount (dB) in which the microwaves leaked to the outer space 114 were actually attenuated.

TABLE 1

| | Non- | Plating | Thermal spraying |
|---|---|---|---|
| | processing | method | method |
| Thickness of | — | 5 | 100 |
| metal film (μm) | | | |
| Input (%) | 100 | 100 | 100 |
| Reflection (%) | 3.25 | 97.0 | 96.1 |
| Transmission (%) | 75.4 | 1.37E−05 | 1.12E−05 |
| Absorption (%) | 2.18 | 3.03 | 3.86 |
| Leakage (%) | 19.1 | 1.45E−03 | 5.30E−04 |
| Leakage attenuation | — | −41.2 | −45.6 |
| ratio (dB) | | | |

As represented in Table 1, in the case of FIG. 4A in which the conductive film 100 was not coated, the reflection was 3.25(%), the transmission was 75.4(%), the absorption was 2.18(%), and the leakage was 19.1(%). That is, 19.1 (%) of the microwaves input to the thermal insulating member 90 was leaked to the outside.

In contrast, in the case of FIG. 4B in which the conductive film 100 was coated, the reflection was 97.0(%), the transmission was 1.37E-05(%), the absorption was 3.03(%), and the leakage was 1.45E-03(%) when the conductive film 100 was coated to a thickness of 5 μm by the plating method. In addition, the leakage attenuation rate at this time was −41.2 (dB). Further, the reflection was 96.1(%), the transmission was 1.12E-05(%), the absorption was 3.86(%), and the leakage was 5.30E-04(%) when the conductive film was coated to a thickness of 100 μm by the thermal spraying method. In addition, the leakage attenuation rate at this time was −45.6 (dB).

The microwave leakage attenuation ratio required for a gate valve structure of a general microwave plasma processing apparatus is known to be about −20 (dB) from the viewpoint of safety. According to the above verification results, when the conductive film 100 was coated on the thermal insulating member 90 by any of the plating method or the thermal spraying method, the microwave leakage attenuation ratio exceeded −40 (dB). Therefore, when the conductive film 100 is coated on the thermal insulating member 90, the leakage of microwaves to the outer space 114 may be suppressed to the extent that sufficient safety is secured. Further, the leakage of microwaves may be suppressed sufficiently as long as the range of coating the conductive film 100 on the thermal insulating member 90 includes the interface between the thermal insulating member 90 and the adjacent chamber and the surface exposed to the outer air.

In Table 1, the conductive film 100 was coated to thicknesses of 5 μm and 100 μm. However, according to the present inventors' verification, it has been found that when the thickness of the conductive film 100 is in the range of 5 μm to 100 μm, the leakage of microwaves to the outer space 114 may be suppressed to the extent that sufficient safety is secured.

Further, it is known that an absorption loss (the “absorption” in Table 1) in the thermal insulating member 90 coated with the conductive film 100 depends on a density of electric current excited from the surface of the conductive film 100 to the rear side, and is involved in a skin depth of the conductive film 100. According to the present inventors' verification, it has been found that as the conductive film 100 becomes thicker, the absorption loss increases so that the microwave may be suppressed from being leaked to the outer space 114. Specifically, when the thickness of the conductive film 100 is at least twice the skin depth, the microwave leakage attenuation ratio may be set to about −20 (dB). That is, in a case where the conductive film 100 is a metal film made of aluminum, the thickness of the conductive film 100 may be 5 μm or more because the skin depth of aluminum is 2.5 μm.

Based on the verification results, the plasma processing apparatus 1 according to the present exemplary embodiment has a configuration in which the conductive film 100 is coated on a predetermined portion of the outer surface of the thermal insulating member 90. Therefore, it is possible to suppress the microwaves, which are leaked from the processing container 10 through the gate valve 12 during the plasma processing, from being leaked to the outside of the apparatus through the thermal insulating member 90, or the interface between the thermal insulating member 90 and the adjacent chamber to the extremely low extent. As a result, the safety of the plasma processing apparatus 1 may be enhanced, and hence, the plasma processing may be performed efficiently and stably.

Further, according to the present exemplary embodiment, the coating of the conductive film 100 on the thermal insulating member 90 is performed by the plating method or the thermal spraying method. That is, the leakage of microwaves may be suppressed by performing a surface treatment on a thermal insulating member 90 which has been used in the prior art with a simple configuration, without introducing a new mechanism or apparatus to suppress the leakage of microwaves. This is also very useful in terms of equipment cost.

Further, in the present exemplary embodiment, even in a case where the coating of the conductive film 100 is performed on the outer surface of the thermal insulating member 90, the insulation of the thermal insulating member 90 is not adversely affected. Hence, the leakage of microwaves to the outside of the apparatus may be suppressed while securing the insulation between the processing container 10 and the transfer chamber 80 as before.

Further, in the present exemplary embodiment, the thermal insulating member 90 and the adjacent chamber (e.g., the processing container 10 or the transfer chamber 80) are connected to each other by performing fastening with, for example, bolts made of resin. When such a connection is performed, the conductive film 100 coated on the thermal insulating member 90 may get a scratch (so-called a use-wear) by the fastening with the bolts.

Therefore, the present inventors have also performed verification about a leakage attenuation ratio of microwaves when the conductive film 100 is scratched. The following Table 2 shows verification results of reflection (%), transmission (%), absorption (%), and leakage (%) of microwaves measured in the verification device 110 when the conductive film 100 was scratched. Further, the verification was performed under the same conditions as those listed in Table 1, except that the conductive film 100 was scratched. Further, as a case where the conductive film 100 was scratched, the thermal insulating member 90 and the adjacent chamber were connected by performing the fastening bolts five times by a force of 5.0 N·m.

TABLE 2

| | Plating method | Thermal spraying method |
|---|---|---|
| Input (%) | 100 | 100 |
| Reflection (%) | 96.3 | 95.0 |
| Transmission (%) | 5.14E−06 | 1.16E−06 |
| Absorption (%) | 3.63 | 5.03 |
| Leakage (%) | 3.79E−04 | 9.26E−04 |
| Leakage attenuation ratio (dB) | −47.0 | −43.2 |

As represented in Table 2, the microwave leakage attenuation ratio was −47.0 (dB) in a case where the conductive film 100 having a film thickness of 5 μm was coated on the thermal insulating member 90 by the plating method. Further, the microwave leakage attenuation ratio was −43.2 (dB) in a case where the conductive film 100 having a film thickness of 100 μm was coated on the thermal insulating member 90 by the thermal spraying method. As a result, it is confirmed that the leakage attenuation ratio of microwaves exceeds −40 (dB) even in a state where the conductive film 100 is scratched. Accordingly, it is found that the safety is secured sufficiently.

It is considered that the use-wear caused on the conductive film 100 coated on the thermal insulating member 90 varies in size and depth depending on sites. However, it is estimated that the security is secured sufficiently as long as the conductive film 100 is coated to the extent that the surface of the thermal insulating member 90 is invisible. Further, even in a case where the surface of the thermal insulating member 90 is visible, it is estimated that the leakage of microwaves is suppressed sufficiently when the use-wear is relatively small.

Exemplary embodiments of the present disclosure have been described with reference to the accompanying drawings, but the present disclosure is not limited thereto. It is evident that various modifications or changes may be conceived by those skilled in the art within the scope of the claims appended herewith, and it will be understood that the modifications or the changes belong to the technical scope of the present disclosure.

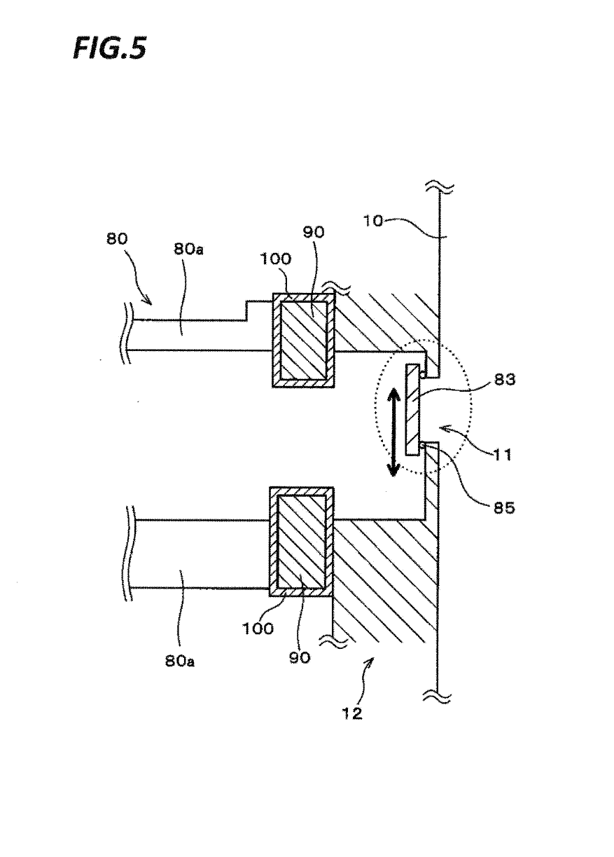

In the above-mentioned exemplary embodiments, descriptions have been made on the configuration in which the conductive film 100 is coated on the interface between the thermal insulating member 90 and the adjacent chamber and the surface exposed to the outer air among the outer surfaces of the thermal insulating member 90, but the present disclosure is not limited thereto. Specifically, for example, the conductive film 100 may be coated on the whole outer surfaces of the thermal insulating member 90, as illustrated in FIG. 5. According to this configuration, the same effects as those in the above-mentioned exemplary embodiments may be obtained. In addition, the leakage of microwaves is further suppressed.

Further, in the above-mentioned exemplary embodiments, the conductive film 100 has been exemplified by a metal film, but not limited thereto. Specifically, the conductive film 100 may be a carbon film or indium tin oxide (ITO).

Further, the plating method or the thermal spraying method has been mentioned as a method of coating the conductive film 100, but other coating methods may, of course, be used. Specifically, a conductive coating, a physical vapor deposition (PVD) method, or a chemical vapor deposition (CVD) method may be used. However, the plating method or the thermal spraying method mentioned in the above exemplary embodiments may be more preferable in terms of workability or cost.

Further, in the above-mentioned exemplary embodiments, descriptions were made on a case where the leakage of microwaves between the processing container and the transfer chamber was suppressed by the plasma processing apparatus using microwaves, but present disclosure is not limited thereto. That is, the present disclosure is applicable to a technique of suppressing the leakage of microwaves between a processing apparatus using microwaves and various devices or chambers incidental thereto. Specifically, the present disclosure is useful to suppress the leakage of microwaves between a plasma processing apparatus and a pressure gauge that measures pressure therein. Further, the workpiece to be processed by the plasma processing of the present disclosure may be any substrate such as, for example, a glass substrate, an organic EL substrate, and a substrate for flat panel display (FPD).

The present disclosure is useful for a plasma processing apparatus that processes a workpiece by generating plasma from a processing gas.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container provided with an opening to carry an object to be processed (“workpiece”) into or out of a chamber adjacent to the processing container;
a microwave introducing mechanism configured to introduce microwaves into the processing container;
an exhaust device configured to evacuate the processing container; and
a thermal insulating member provided between an outer surface of a gate valve that is provided near the opening and the chamber adjacent to the processing container;
wherein the thermal insulating member is coated with a conductive film at least on a surface facing the outer surface of the gate valve, a surface facing the chamber adjacent to the processing container, and a surface exposed to outer air.

2. The plasma processing apparatus of claim 1, wherein the conductive film is coated on a whole outer peripheral surface of the thermal insulating member.

3. The plasma processing apparatus of claim 1, wherein the conductive film is coated by a plating method or a thermal spraying method.

4. The plasma processing apparatus of claim 1, wherein a thickness of the conductive film is 5 μm to 100 μm.

5. The plasma processing apparatus of claim 1, wherein the thermal insulating member is formed of an insulating resin.
